(19) United States
(12) Patent Application Publication
(10) Pub. No.: US 2012/0152306 A1
(43) Pub. Date: Jun. 21, 2012

(54) INFLATABLE SOLAR CELL ARRAY

(75) Inventors: Mickey Iqbal, Plano, TX (US); John Falk Kelley, Clarkesville, GA (US); Calvin D. Lawrence, Lithonia, GA (US)

(73) Assignee: INTERNATIONAL BUSINESS MACHINES CORPORATION, Armonk, NY (US)

(21) Appl. No.: 12/968,408

(22) Filed: Dec. 15, 2010

(51) Int. Cl. H01L 31/045

(52) U.S. Cl. 136/245; 29/592.1

(57) ABSTRACT

The present invention relates to a solar cell array, which includes a flexible, inflatable membrane. Multiple flexible photovoltaic cells are positioned on the top surface of the flexible membrane. The solar cell array also includes a container for the inflatable membrane and a structure for automatically inflating the membrane when at least one predetermined condition is met.

### BACKGROUND OF THE INVENTION

### Field of the Invention

The present invention relates to solar cells and, more particularly, to inflatable solar cell arrays.

Solar energy has long been looked to as a potential solution to the ever increasing power needs of the planet's population. It is considered to be one of the most environmentally friendly sources of energy that can be used on earth. Photovoltaic cells, commonly called solar cells, are well-known tools which convert solar radiation into direct current electricity using semiconductors that exhibit the photovoltaic effect. The photovoltaic effect is the creation of electric current in a material upon exposure to light. When more power required than a single cell can produce, typically, solar cells are collected in multiples and are connected together to form photovoltaic arrays.

Conventional photovoltaic arrays are commonly used as fixed solar panels mounted on a frame. However, these conventional fixed solar panels typically suffer from important limitations. Fixed solar panels have a propensity to be hard to store, deploy, and relocate. They are typically deployed and locked into a rigid structure. Fixed solar panels are also subject to weather conditions. For example, it might be desirable to remove or relocate solar panels if they get covered by snow. Therefore, there is generally a need for a portable and easily deployable solar cell array.

### BRIEF SUMMARY OF INVENTION

The present invention addresses the aforementioned need by setting forth a portable solar array that deploys by inflation. The new inflatable movable solar array automatically opens when the appropriate threshold is reached. Advantageously, these repeatable automatic inflation and deflation mechanisms help to overcome limitations of the fixed solar arrays like those described above.

In accordance with an embodiment of the present invention, a solar cell array comprises a flexible, inflatable membrane having a top surface and a bottom surface, wherein a plurality of flexible photovoltaic cells are positioned on the top surface of the flexible, inflatable membrane. Moreover, the solar cell array further comprises a container which holds and protects the delicate flexible, inflatable membrane. Finally, a third element of the solar array, according to an embodiment of this invention, is a deployment mechanism for automatically inflating the flexible membrane provided at least one predetermined condition is met.

These and other features and advantages of the present invention will become apparent from the following detailed description which is to be read in conjunction with the accompanying figures.

### BRIEF DESCRIPTION OF THE SEVERAL VIEWS OF THE DRAWINGS

FIG. 1 shows a cross section of a conventional solar cell array;

FIG. 2 is a perspective view of the container containing the solar array membrane, the solar array being in its stored configuration;

FIG. 3 is a perspective view showing the container of FIG. 2 with the solar array membrane partially deployed;

FIG. 4 is a perspective view, similar to FIG. 3, with the solar array membrane fully deployed and inflated according to the present disclosure;

FIG. 5 illustrates a cross section of an alternate embodiment of a solar cell array; and

FIG. 6 is a flow chart showing the operation of the deployment mechanism according to the present disclosure.

### DETAILED DESCRIPTION OF INVENTION

This invention will be illustrated herein in conjunction with exemplary photovoltaic cells for use in solar cell arrays. It should be understood, however, that the invention is not limited to the particular materials, elements, and features shown and described herein. Modifications to the illustrative embodiment will become apparent to those skilled in the art in light of the following description.

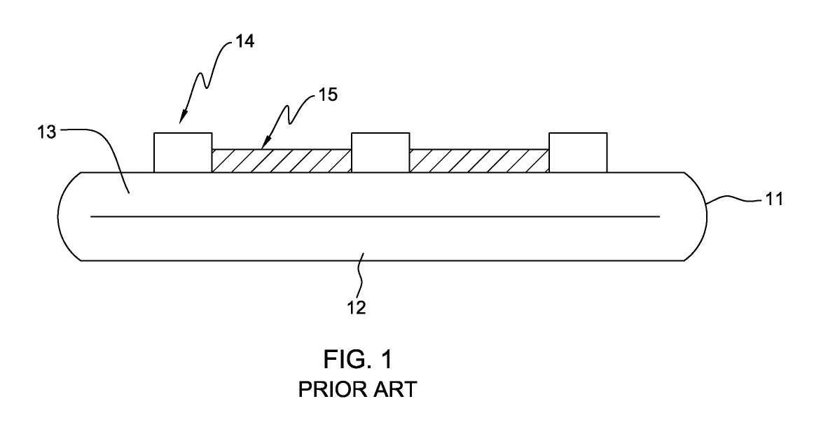

FIG. 1 shows a general example of a conventional inflatable solar cell array. The solar cell array may include a flexible membrane 11. This membrane can be composed of any material suitable for inflating. The membrane can be composed of, for example, a rubber-like material. The membrane 11 may include a top surface 13 having one or more solar cells 14 positioned on it and a bottom surface 12. The solar cells 14 may be connected with bus bars 15 as is known to those of ordinary skill in the art. The connections between the solar cells 14 may be serial connections, parallel connections or any combination thereof so that the electricity generated by each cell can be transferred out of the solar cell array.

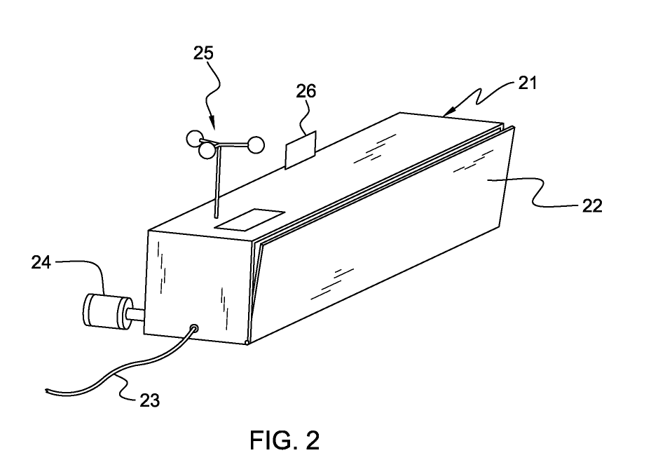

FIG. 2 shows a perspective view of an illustrative embodiment of the automatically deployable solar array in its stored configuration in accordance with aspects of the present invention. FIG. 2 depicts a container 21. A hinged cover 22 may be provided to close the container 21. When the cover 22 is closed, the enfolded solar cell array will be protected during unfavorable weather conditions or during storage or transport. In a preferred embodiment the container can be a long box, as shown in FIG. 2. The box may have dimensions of 20′×24″×24″. A connection cable 23 extends from this container 21 for transfer of electricity out of the solar array.

The container 21 has an air pump 24 mounted on one side. In accordance with an embodiment of the invention air pump 21 can be a two-way mode air pump. In other words, a single pump may be utilized to both inflate and deflate membrane 11. When open, air pump 24 will draw air from the atmosphere to inflate membrane 11. The same air pump 24 may be used as a vacuum source to draw air from membrane 11 to deflate the membrane. In a preferred embodiment air pump 24 may include a battery (not shown) or any other power source known in the art.

In accordance with an embodiment of the invention container 21 has also one or more sensors 25 mounted on one of the sides that can be utilized as detectors for bad weather or other dangers, such as dust or impact from moving objects. These sensors 25 can include any means for determining whether a weather condition such as snow or high winds is present. The sensing components may include a temperature detector, a lightning detector, a wind speed detector and a snow detector. Advantageously, sensor 25 can send a signal to air flow controller 26 when it detects that the weather condition is present. Based on the received information, air flow controller 26 may make a decision whether membrane 11 needs to be inflated or deflated. When conditions are right (i.e., when it is not snowing and the wind is not blowing) air flow controller 26 will trigger air pump 24 to deploy membrane 11 by inflation.

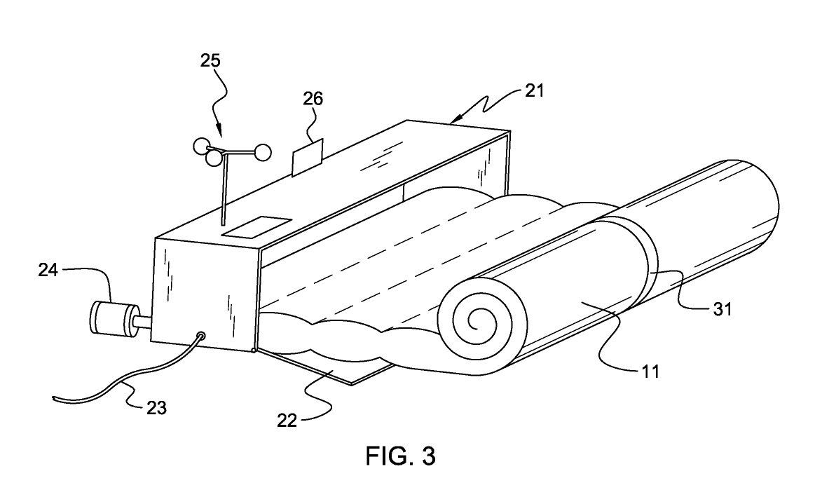

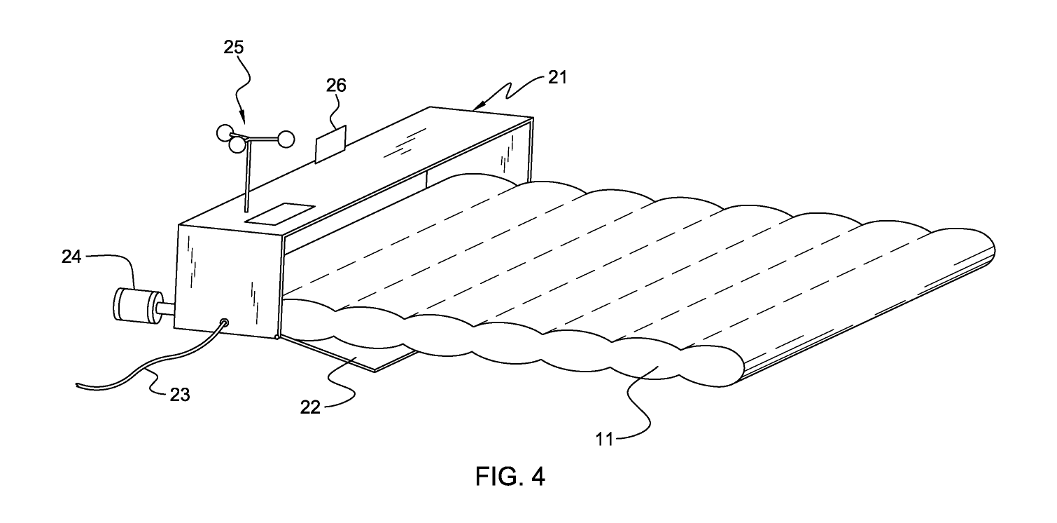

FIGS. 3 and 4 show the solar array partly deployed and fully deployed, respectively. It must be noted that the inflation process will force hinged cover 22 to open, as can be seen in FIG. 3. In accordance with one embodiment of the invention, the deployment mechanism includes a flexible member 31 attached to the bottom surface of flexible membrane 11. Flexible member 31 is utilized as a roll up mechanism during the deflation process when the air is removed from membrane 11. In a preferred embodiment the flexible member can be a series of strings or any other material that may demonstrate the ability to return to some previously defined shape. Membrane 11 will wrap in a curved shape rolling back into container 21 as it is deflated. FIG. 4 shows flexible membrane 11 fully inflated.

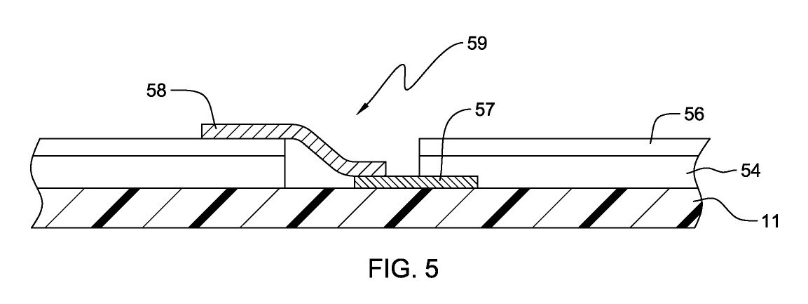

The present invention overcomes the prior art disadvantages by permitting a wide variety of configurations to be achieved with the solar cells—including both rigid as well as flexible structures. FIG. 5 illustrates an alternative embodiment of the present invention. Flexible solar cells may be fabricated by depositing two thin layers of photosensitive material 54 and 56 on or above at least a portion of flexible membrane 11. In this context, photosensitive material may comprise one or a combination of materials, and may comprise organic materials, inorganic material, or a combination thereof, such as one or more types of semiconducting solid oxides, such as oxides of titanium, tantalum, tungsten, vanadium, niobium, zinc, tin, or any combination thereof, or one or more sulfides of tin, iron, cadmium, or copper, for example; although, the claimed subject matter is not so limited. Layers 54 and 56 may have electrical isolation regions 59 formed by ordinary methods such as masking during deposition, etching or other methods known to those of ordinary skill in the art. Layers of electrically conductive material 57 and 58 are deposited as shown in FIG. 5, which electrically connect energy generating regions. One skilled in the art will recognize that electrically conductive material of layer 58 may extend elevationally over and above photosensitive layer 56. Likewise, conductive layer 57 may be deposited beneath, at least partially, photosensitive layer 54.

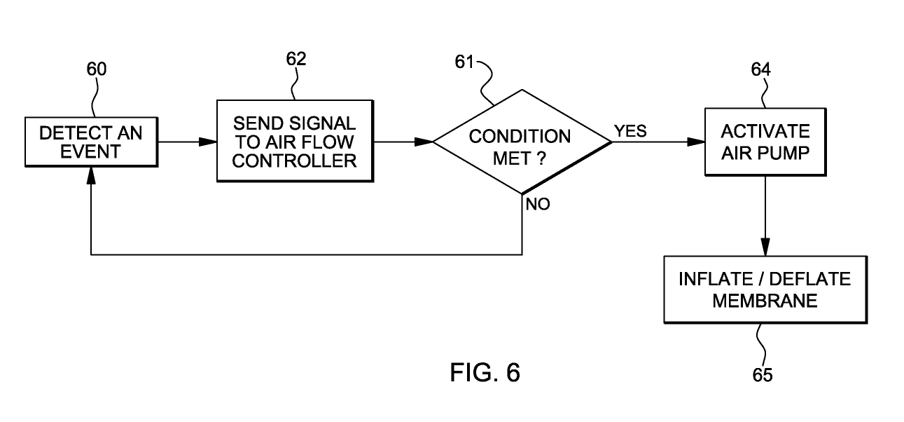

FIG. 6 is a flow chart showing the operating logic of the deployment mechanism according to another embodiment of the present disclosure. The process begins when sensors 25 detect an event of interest 60, such as snow or high wind. Next, a signal is sent to air flow controller 26, as shown in step 62. In an exemplary embodiment, the controller is then operative to decide whether the event meets any of the predetermined conditions 61. If the check result in step 61 is “YES”, that is, if, for example, snow is detected, controller 26 determines that air pump 24 must be activated 64 to deflate flexible membrane 11, as shown in step 65. If the check result in step 61 is “NO”, controller 26 determines that air pump 24 does not need to be activated and the process returns to step 60 to continue to listen for an event of interest.

Thus, an advantage of the present invention is to provide a solar cell array by permitting a wide variety of configurations to be achieved with the solar cells—including both rigid as well as flexible structures. Another advantage of this invention is its compactness, thus facilitating its overall portability or discrete transport, including transport to outer space. Yet another advantage of the present invention is the ability to automatically inflate/deflate when predetermined threshold conditions are met.

Although illustrative embodiments of the present invention have been described herein with reference to the accompanying figures, it is to be understood that the invention is not limited to the embodiments disclosed, but is capable of numerous rearrangements, modifications, and substitutions of parts and elements without departing from the spirit of the invention.

What is claimed is:

1. A solar cell array comprising:
a flexible, inflatable membrane having a top surface and a bottom surface, wherein a plurality of flexible photovoltaic cells are positioned on the top surface of said flexible membrane;
a container for containing said flexible, inflatable membrane; and
a structure for automatically inflating said flexible, inflatable membrane when at least one predetermined condition is met.

2. The solar cell array of claim 1, wherein said container comprises a container body and a hinging cover.

3. The solar cell array of claim 2, wherein said container comprises a box.

4. The solar cell array of claim 1, wherein said structure comprises an air pump mounted to said container for generating a flow of air to inflate said flexible, inflatable membrane.

5. The solar cell array of claim 1, wherein said structure comprises at least one sensor for detecting an event.

6. The solar cell array of claim 4, wherein said air pump comprises a two-way mode air pump mounted to said container for automatically inflating said flexible, inflatable membrane when said at least one predetermined condition is met and for automatically deflating said flexible, inflatable membrane when another at least one predetermined condition is met.

7. The solar cell array of claim 4, wherein said structure comprises an air flow controller, and wherein said air flow controller triggers said air pump when the determination that said event meets said at least one predetermined condition is obtained.

8. The solar cell array of claim 1, wherein a flexible member is attached to said bottom surface of said flexible, inflatable membrane, and wherein said flexible member provides means to return said flexible, inflatable membrane to a rolled up configuration.

9. The solar cell array of claim 6, wherein said structure comprises a battery mounted to said container and wherein said battery provides power to said air pump.

10. A method for assembling a solar cell array comprising:
providing a flexible, inflatable membrane having a top surface and a bottom surface, wherein a plurality of flexible photovoltaic cells are positioned on the top surface of said flexible membrane;
providing a container for containing said flexible, inflatable membrane; and
automatically inflating said flexible, inflatable membrane when at least one predetermined condition is met.

11. The method of assembling a solar cell array of claim 10, wherein said container comprises a container body and a hinging cover.

12. The method of assembling a solar cell array of claim 11, wherein said container comprises a box.

13. The method of assembling a solar cell array of claim 10, further comprising mounting an air pump to said container for generating a flow of air to inflate said flexible, inflatable membrane.

14. The method of assembling a solar cell array of claim 10, wherein said structure comprises at least one sensor for detecting an event.

15. The method of assembling a solar cell array of claim 10, further comprising mounting a two-way mode air pump to said container, wherein said air pump causes said flexible, inflatable membrane to automatically inflate when said at least one predetermined condition is met and causes for said flexible, inflatable membrane to automatically deflate when another at least one predetermined condition is met.

16. The method of assembling a solar cell array of claim 13, wherein said structure further comprises an air flow controller, and wherein said air flow controller triggers said air pump when the determination that said event meets said at least one predetermined condition is obtained.

17. The method of assembling a solar cell array of claim 10, wherein a flexible member is attached to said bottom surface of said flexible, inflatable membrane, and wherein said flexible member provides means to return said flexible, inflatable membrane to a rolled up configuration.

18. The method of assembling a solar cell array of claim 15, further comprising attaching a battery to said container, wherein said battery provides power to said air pump.

19. An inflatable photovoltaic collector, comprising:
a flexible, inflatable membrane having two thin layers of photosensitive materials deposited thereon, said materials having electrically isolating regions and conductive material contacts;
a container for said flexible, inflatable membrane; and
a structure for inflating said flexible, inflatable membrane in response to a control condition.
